(19) United States
(12) Patent Application Publication
(10) Pub. No.: US 2017/0089953 A1
(43) Pub. Date: Mar. 30, 2017

(54) CONTOUR GENERATION OF PROMPTED DATA SIGNAL

(71) Applicant: Microsoft Technology Licensing, LLC, Redmond, WA (US)

(72) Inventors: Darryl Robert Liang, Incline Village, NV (US); Jeffrey J. Halnon, Richmond, CA (US); Gary F. Grimm, JR., Duvall, WA (US)

(21) Appl. No.: 14/866,510

(22) Filed: Sep. 25, 2015

(51) Int. Cl. G01R 13/02; H04N 17/04

(52) U.S. Cl. CPC G01R 13/02; H04N 17/045

(57) ABSTRACT

The testing of a received data signal accessed from a device under test. Communication circuitry first generates an instruction that causes the device under to emit the data signal towards quality parameter contour generation circuitry. The contour generation circuitry is then configured to generate quality parameter (e.g., bit error ratio) contour of the data signal, which is then received at the contour generation circuitry. The generated contour map may then be evaluated to diagnose the performance of the device under test in emitting the data signal. For instance, each device under test may be evaluated after manufacture. The quality parameter contour generation circuitry may be embedded within an electronic device, such as a consumer electronic device. A diagnostic component within the electronic device is configured to use the quality parameter contour generated by the contour generation circuitry to self-test the device.

### BACKGROUND

Electronic devices have revolutionized the way human beings work, play, and communicate. In order for electronic devices to communicate data with the outside world, it is important that the electronic device encode data to be transmitted on a signal that is suitable for transmission over one or more channels. Also, it is important that the electronic device receives signals over one or more channels that are of suitable quality that appropriate data may be decoded from the signal. Accordingly, designers and testers often measure the characteristics and quality of a data signal generated by devices under test (DUTs).

One way to precisely measure the key parameters of a signal is via the use of an oscilloscope. It is practical during the design of a device under test to use the oscilloscope to measure signals emitted by prototypes during various design phases. However, it is less practical to use the oscilloscope to measure signal quality for each manufactured device that is patterned after a final design. This is especially true for devices that are manufactured in volume.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

At least one embodiment described herein relates to the testing of a received data signal accessed from a device under test. Communication circuitry first generates an instruction that is recognizable by the device under test as triggering the device under test to emit the data signal towards quality parameter contour generation circuitry. The contour generation circuitry then generate a quality parameter contour of the data signal, which is then received and sunk at the contour generation circuitry. The generated contour may then be evaluated to diagnose the performance of the device under test in emitting the data signal. The quality parameter contour may be a rough approximation, which is less accurate than an oscilloscope. However, the quality parameter contour may still be of sufficient granularity to perform meaningful diagnostics on the device under test, and without requiring significant other dedicated and bulky testing equipment. Accordingly, diagnostics may be performed to test the technical parameters of an emitted data signal in many more locations. For instance, each device under test may be evaluated after manufacture.

At least one embodiment described herein relates to the use of quality parameter contour generation circuitry within an electronic device, such as a consumer electronic device. A diagnostic component within the electronic device is configured to use the quality parameter contour generated by the contour generation circuitry to perform diagnostics on the data signal accessible at the electronic device. Accordingly, the electronic device may be self-diagnosing of signals received or generated by the electronic device using the contour generation circuitry and the diagnostic component, which both reside within the electronic device. Because such components are small, many more electronic devices may be self-diagnosing.

This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of various embodiments will be rendered by reference to the appended drawings. Understanding that these drawings depict only sample embodiments and are not therefore to be considered to be limiting of the scope of the invention, the embodiments will be described and explained with additional specificity and detail through the use of the accompanying drawings in which:

FIG. 1 illustrates a testing environment in which a device under test is being tested to verify proper output of a data signal;

FIG. 2A illustrates an example quality parameter contour in the form of a map in which each region has an associated quality parameter—in this case a bit-error rate;

FIG. 2B illustrates an example quality parameter contour in the form of a set of constant quality tracking lines/curves in which each line/curve represents areas of a corresponding constant value in the quality parameter;

FIG. 3A illustrates an example eye diagram of a binary phase shift keyed (BPSK) system;

FIG. 3B illustrates an example eye diagram of a 4 level pulse amplitude modulation (PAM) system;

FIG. 4 illustrates a flowchart of a method for testing a device under test, and which may be performed in the environment of FIG. 4;

FIG. 5 illustrates an electronic device (e.g., a consumer electronic device) capable of self-testing; and

FIG. 6 illustrates a module-level circuit diagram of example of an example the testing device of FIG. 1.

### DETAILED DESCRIPTION

At least one embodiment described herein relates to the testing of a received data signal accessed from a device under test. Communication circuitry first generates an instruction that is recognizable by the device under test as triggering the device under test to emit the data signal towards quality parameter contour generation circuitry. The contour generation circuitry then generates a quality parameter contour of the data signal, which is received and sunk at the contour generation circuitry. The generated contour may then be evaluated to diagnose the performance of the device under test in emitting the data signal. The quality parameter contour may be a rough approximation, which is less accurate than an oscilloscope. However, the quality parameter contour may still be of sufficient granularity to perform meaningful diagnostics on the device under test, and without requiring significant other dedicated and bulky testing equipment. Accordingly, diagnostics may be performed to test the technical parameters of an emitted data signal in many more locations. For instance, each device under test may be evaluated after manufacture.

At least one embodiment described herein relates to the use of quality parameter contour generation circuitry within an electronic device, such as a consumer electronic device. A diagnostic component within the electronic device is configured to use the quality parameter contour generated by the contour generation circuitry to perform diagnostics on the data signal accessible at the electronic device. Accordingly, the electronic device may be self-diagnosing of signals received or generated by the electronic device using the contour generation circuitry and the diagnostic component, which both reside within the electronic device. Because such components are small, many more electronic devices may be self-diagnosing.

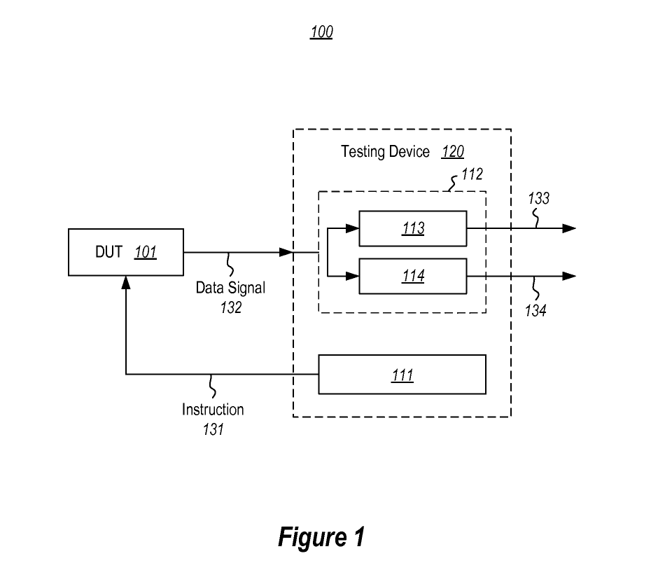

FIG. 1 illustrates a testing environment 100 in which a device under test 101 is being tested to verify proper output of a data signal 132. As an example, the device under test 101 might be the actual device that generates the data signal, a device that simply passes through the data signal, or a hybrid that generates some output data signal based on one or more input output signals. Nevertheless, in the environment 100, one of more quality parameters of the data signal 132 are verified. The device under test 101 may also be a combination of devices. For instance, if a data signal is to be tested after being generated by a first device, and then passed through a connector, then the combination of the first device and the connector may be viewed as a device under test 101 as the term is used herein.

An example of a quality parameter is a bit-error ratio. A “bit-error ratio” is a number of bit-errors divided by the number of bits checked. A type of “bit-error ratio” is a “bit-error rate” if the number of bits checked corresponds to the number of bits encountered in the data signal in a unit time (e.g., one second). The term “bit-error” is to be broadly construed herein as the principles described herein are not limited to the patterns that the device under test 101 may produce.

As an example, the device under test 101 may be prompted to generate a Pseudo Random Binary Sequence (PRBS) of various forms (e.g., PRBS7, PRBS15, PRBS31). In the case of such a PRBS stream, a comparison of the received data with the expected stream is done and any differences would be considered a bit error. The stream comparison can be done at a bit level or at a group-of-bits level (byte or word or even 20 bits).

Alternatively, the device under test 101 could be prompted to generate a live data stream. In the case of a live data bit stream, such as a TMDS bit stream from an HDMI Source DUT, a bit sampler could be used. 10 bits are combined to make a TMDS symbol. This received symbol is compared to a set of valid symbol combinations. If the combination is not valid, this is a Symbol Error, which may then be used to determine the bit-error ratio.

The device under test 101 might also generate a short repeating data stream. For some interfaces, it can be prompted to generate the “Nyquist Rate”, which is basically the fastest toggle rate, which actually looks like a square wave clock. Accordingly, the bit-error in the latter case would just be testing the quality of this toggling clock.

The principles described herein are not limited to the type of data signal, but in one example, the data signal 132 is a video signal. However, the data signal 132 may be any type of data signal including signals representing media (e.g., audio, image, video, holographic, tactile, combinations thereof, and so forth) or strict data signals (e.g., representing binary data such as executables or general network traffic). Although the data signal 132 may be a digital signal, the principles described herein may also operate in the case of a data signal 132 being an analog signal.

Testing is critical for video generation devices, in particular, since the bandwidth requirements for video communication may be quite high, in the megabits per second (Mbps) and even into the Gigabits per second (Gbps) region. For instance, in the generation of a 1080P signal, there are approaching a million pixels per frame, and each frame has data for each pixel. Furthermore, there are 60, 120, 240 and even more frames per second that constitute the video signal. The bandwidth requirements of some video signals have increased even further due to even higher resolution video, in which there are many more pixels per frame. Furthermore, video for multiple channels may be communicated over a single wire. With such high bandwidth data signals often being communicated over a signal copper wire, it is important to test the quality of the video signal after coming through that copper wire, since the bandwidth capacity of the channel is often pushed towards its limit, resulting in some give in signal quality. As an example, in addition to the copper wire, the channel could include everything from the time of transmission in the device under test 101 (including balls or pins on the transmitting integrated circuit, the vias, the printed circuit board, the connectors, and so forth).

Referring back to FIG. 1, the testing environment 100 also includes a testing device 110 that actually generates a quality parameter contour 133 of the data signal 132 that is under test.

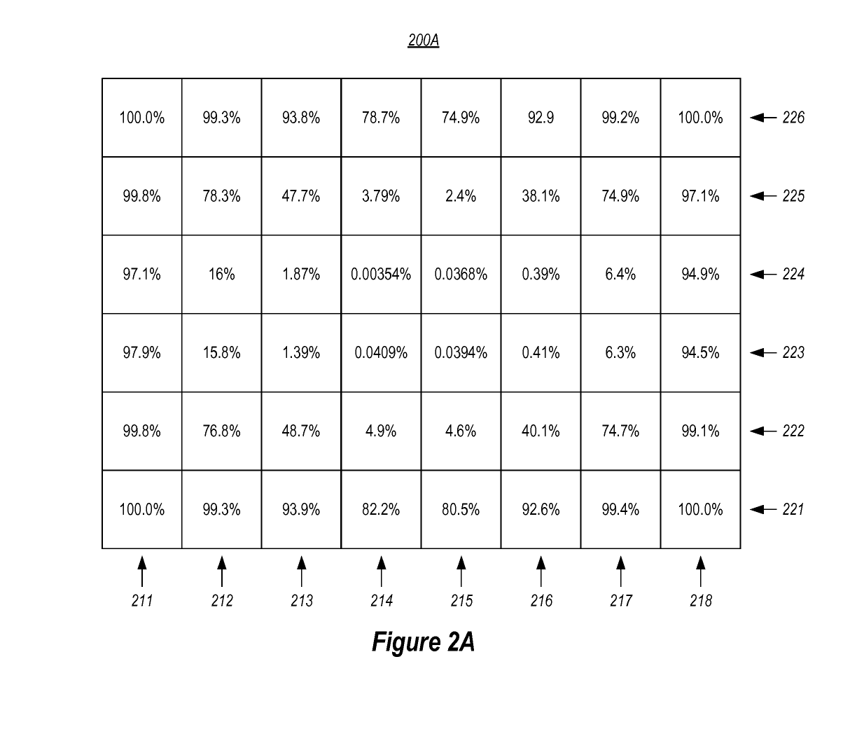

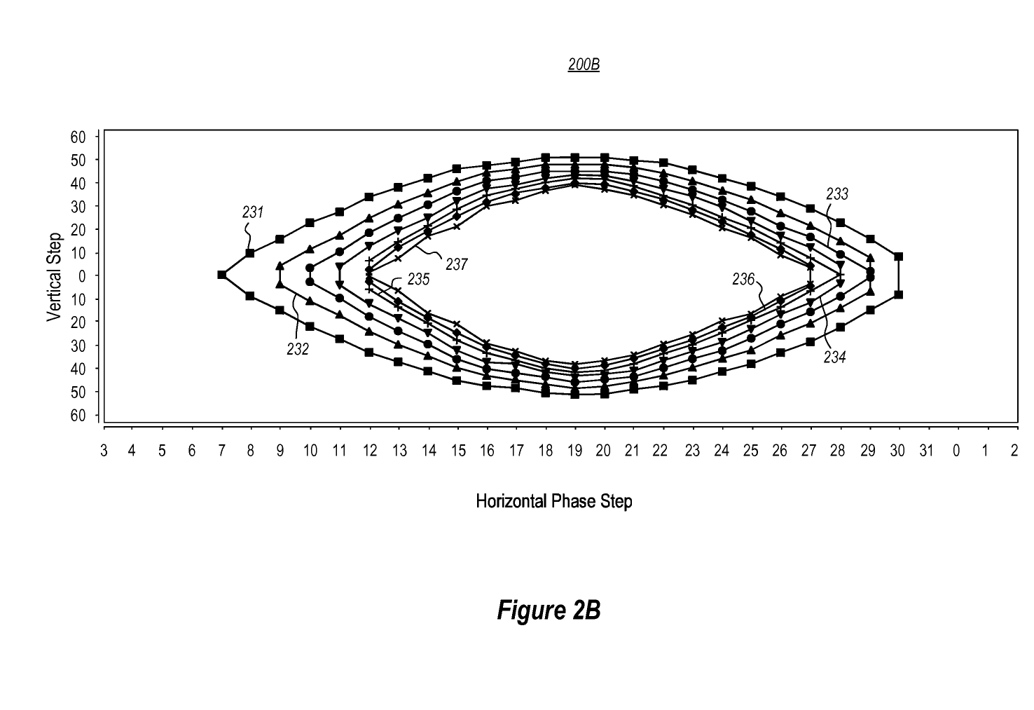

FIG. 2A illustrates an example quality parameter contour in the form of a quality parameter map 200A, in which a quality parameter (in this case, a bit-error ratio) is associated with each position on the map. This quality parameter contour map 200 illustrates various quality parameter measurements corresponding to numerous samplings of overlaid information windows corresponding to a bit. The quality parameter of each region is obtained by 1) varying the phase and amplitude offset to get into sampling of the particular region of the overlaid information window, 2) sampling the signal in that region for the quality parameter, and 3) determining the quality parameter from the sample(s). This is repeated for each region to obtain the contour map. Currently samplers have 32 to 64 horizontal phase steps and 64 to 128 vertical amplitude steps.

For instance, in FIG. 2A, to keep things simple, the quality parameter is a bit-error ratio, and there are eight phase regions 211 through 218, and six amplitude regions 221 through 226, resulting in 48 total regions, each having an associated quality parameter measurement. As an example, the bit-error ratio for phase region 213 and amplitude region 222 is 48.7 percent in this example, representing that this region is close to the edge of the eye pattern. The bit-error ratio for phase region 215 and amplitude region 223 is 0.0394 percent in this example representing that this region is within the center region of the eye.

FIG. 2B illustrates another example of a quality parameter contour in the form of a set of constant quality parameter value lines/curves 231, 232, 233, 234, 235, 236 and 237. Here, each line/curve is shaped roughly as an American football, and represents a collection of lines that couple sample points at which the constant quality parameter value was measured. The line/curve 237 will represent a high quality signal (e.g., a low bit-error ratio), and the quality will decline for each successive external line/curve 236 through 231. The line/curve 231 will represent a low quality signal (e.g., a high bit-error ratio). As an example, line/curve 237 might represent those areas with a bit-error ratio of 10̂-12, which each succeeding external line/curve representing one higher order of magnitude on the bit-error ratio. For instance, line/curve 236 might represent those areas with a bit-error ratio of 10̂-11, and so forth, until line/curve 231 represents those areas with a bit-error ratio of 10̂-6 (or 0.0001 percent). Accordingly, the term “quality parameter contour” as used herein is to be broadly construed.

Accordingly, the bit-error ratio contour may be thought of as a very rough approximation of an eye diagram for a signal. An eye diagram is an oscilloscope display in which a digital data signal from a receiver is repetitively sampled and applied to the vertical input, while the rising or falling edge of the data clock is used to trigger the horizontal sweep. It is so called because, for several types of coding, the pattern looks like a series of eyes between a pair of rails.

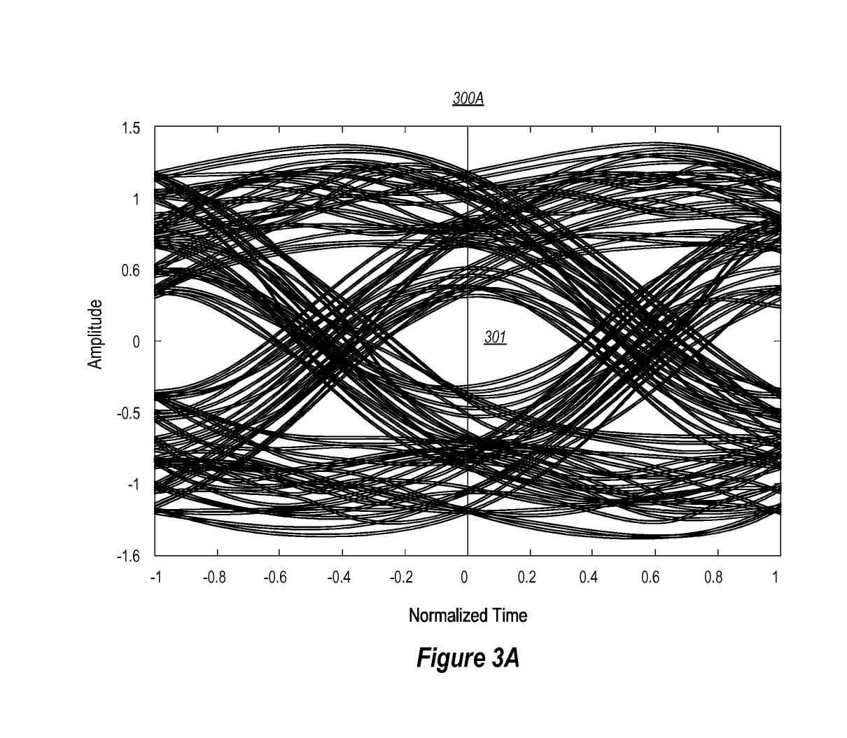

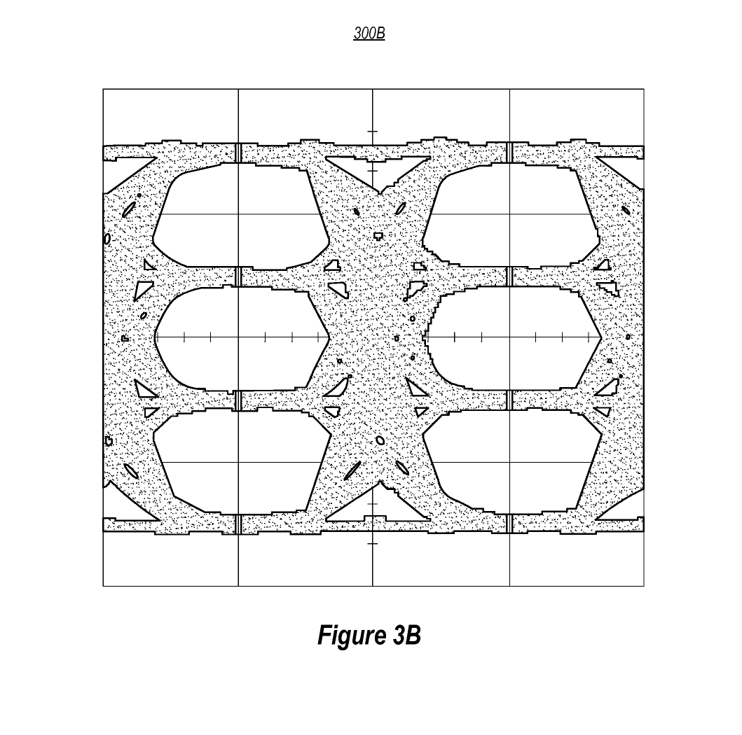

For instance, FIG. 3A illustrates an example eye diagram 300A of a binary phase shift keyed (BPSK) system. Note the appearance of an eye shaped form having an approximate center 301—hence the term “eye diagram” or “eye pattern”. FIG. 3B illustrates an example eye diagram of a 4 level pulse amplitude modulation (PAM) system. In conventional testing, the more open the eye is, the better the quality of the signal. As the eye becomes more and more closed, quality deteriorates and information becomes more difficult to extract. The more sensitive the information type is to information loss, the greater the cost to perceived quality of the signal.

The eye diagram generated by an oscilloscope is very high resolution. However, the quality parameter contour 133 (e.g., see FIGS. 2A and 2B for an example) is much more granular. For instance, compare FIGS. 2A and 2B to FIG. 3A. Nevertheless, an oscilloscope is not needed to generate the quality parameter contour 133, and the quality parameter contour 133 is still helpful information that may be suitable for some purposes. As an example, while an oscilloscope may be used in the testing of the design of a product, the quality parameter contour 133 may be used as a rough check after manufacturing of the each unit of the product to make sure there are no substantial deviations from the design such as might be introduced by minor variations and real life variability that tends to insert itself in the manufacturing process. For instance, the quality parameter contour 133 may be tested for a sampling of manufactured products of a given design, or even for all manufactured products of a given design.

In one embodiment, because the testing device 110 generates such a course contour, it can be made quite small, and thus included within the same physical form as the device under test 101, allowing the device under test 101 to be self-diagnosing. Accordingly, the testing may be performed after manufacturing, or even after being shipped, allowing the device under test 101 to perform periodic diagnostics during its lifetime of use.

The testing device 110 includes device under test communication circuitry 111 and an integrated circuit 112. The device under test communication circuitry 111 may be implemented as a field programmable gate array, although not required. The integrated circuit 112 may also be a field programmable gate array. In one embodiment, both the device under test communication circuitry 111 and the integrated circuit 112 are implemented on a single field programmable gate array chip.

The device under test communication circuitry 111 is configured to generate an instruction 131 that is structured to trigger the device under test 101 to emit the data signal 132 towards contour generation circuitry 113 that operates on the integrated circuit 112. The data signal 132 is received and potentially also sunk (i.e., not re-driven or passed through to another circuit) at the contour generation circuitry 113. Optionally, the testing device 110 also includes a pass through circuit 114 that is configured to pass through (as represented by arrow 134) a received signal 132 when the contour generation circuitry 113 can operate when pass through circuit 114 is passing through the data signal. The pass through circuit 114 may also operate to establish and channel the received data signal 132 to the contour generation circuit 113 when the contour generation circuitry 113 is operating to receive and sink the data signal 132 in order to generate the contour map 133.

The pass through circuit 114 may be used when the contour generation circuit is to generate the quality parameter contour of the data signal, while still allowing downstream circuitry to perform their own testing, such as for signal integrity of functionality. In some cases, the data signal 132 may be higher bandwidth signal when received and sunk at the contour generation circuit 113, but a lower bandwidth signal when passed through the testing circuit (as might be the case when performing functional analysis on lower bandwidth signals). Accordingly, the testing device 110 may itself perform testing of the device under test 101 within the testing environment 100 as well as potentially facilitate testing of the device under test 101 by channeling signals to other testing devices.

In one example, the integrated circuit 112 may be an off-the-shelf component, such as perhaps a repurposed device configured to perform a different primary function that is different than generating a contour map of the data signal. As an example, the integrated circuit 112 might be a retimer, configured to perform retiming, a re-driver, a buffer, any other digital circuit, or perhaps may be part of cable, such as a video cable. The testing circuit 100 may be incorporated within a consumer device, such as perhaps a television, video player, and so forth. Examples of current off-the-shelf components that may be used to generate a bit-error ratio contour includes TI DS125DF410SQE, Altera Stratix V series, Altera Arria 10 series, Xilinx Kintex-7 series, like XC7K70T-1FBG484C, and IDT 89HT0816PYBBCG with Eye Contour tool.

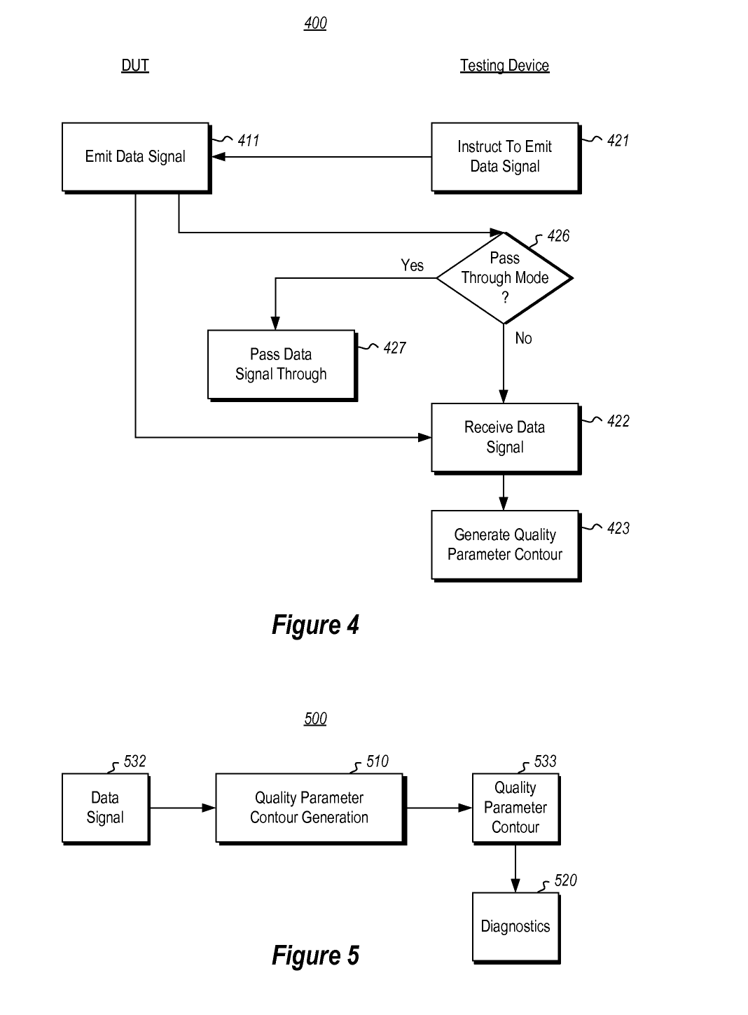

FIG. 4 illustrates a flowchart of a method 400 for testing a device under test. As an example, the method 400 may be performed by the testing device 110 of FIG. 1 with respect to the data signal 132 generated by the device under test 101. Some acts of the method 400 are performed by the device under test as represented in the left column of FIG. 4 under the heading “DUT” (e.g., device under test 101 of FIG. 1), and which are labelled in the 410's. Other of the acts of the method 400 are performed by the testing device (e.g., testing device 110 of FIG. 1) as represented in the right column of FIG. 4 under the heading “Testing Device”.

First, a device under test communication circuitry communicates with the device under test (act 421) so to as cause the device under test to send a data signal towards the integrated circuit (act 411). Referring to FIG. 1, the testing device 110 (or more specifically the device under test communication circuitry 111) emits an instruction signal 131 that causes the device under test 101 to emit the data signal 132. Although only one data signal 132 is illustrated in FIG. 1, the device under test 101 may emit multiple data signals that are subject to evaluation. For instance, the separate data signals may be communicated each over separate data signal lines, with perhaps a clock signal being communicated on yet another line. An example of a connector having multiple data lines and a single clock line is the HDMI standard for communication of high bandwidth video signals.

The instruction signal 131 may follow a certain standard and include standard structures. The instruction signal 131 may be in response to the device under test 101 communicating its video source capabilities via some known or yet to be developed standard. For instance, video sourcing capabilities may be conventionally expressed within an Extended Definition Identification Data (EDID) data structure. Likewise the video utilization capability of the testing device may be communicated using the same standard.

The integrated circuit receives (act 422) the received data signal (act 422) and generates a quality parameter contour of the received data signal (act 423). For instance, in FIG. 1, the integrated circuit 112 (or more specifically the contour generation circuitry 113) receives the data signal 132, and in the process of generating the quality parameter contour 133 ends up sinking the data signal

In one embodiment, whether or not the integrated circuit receives (act 422) (and thus generates the quality parameter contour of the received data signal) depends on whether or not the integrated circuit is acting in pass through mode (“decision block 426). In that case, if the integrated circuit is not acting in pass through mode (“No” in decision block 426), then the integrated circuit receives (act 422) the data signal, and generates the quality parameter contour (act 423). If the integrated circuit is acting in pass through mode (“Yes” in decision block 426), then the signal is, alternatively or additionally, permitted to pass through the testing circuit (act 427). For instance, in FIG. 1, the data signal 132 is permitted to pass through the testing circuit 110 as signal 134. When acting in pass through mode, the testing circuit passes through all communications going to and from the device under test 101. Accordingly, control signals from other devices may pass through the testing circuit 110 to be communicated to the device under test 101.

The testing device may alternate between pass through mode and non-pass through mode. Accordingly, the testing device 110 may occasionally sample the data signal 132 to verify its quality parameter contour. During this time, the data signal 132 may be prevented from passing through the testing circuit to downstream signal consumers. This may be helpful when performing eye diagram analysis on high bandwidth signals and for which functional analysis by downstream video consumers would not be helpful (e.g., perhaps downsteam video consumers are incapable of supporting higher data rates). The device under test communication circuitry may periodically change the format of the video signal provided by the device under test so as to allow a proper understanding of which signal formats the device under test is fully capable of emitting and communicating with acceptable quality.

FIG. 5 illustrates an electronic device 500 (e.g., a consumer electronic device) capable of self-testing. The electronic device 500 includes quality parameter contour generation circuitry 510 configured to generate a quality parameter 533 of a data signal 532 accessible at the electronic device. The data signal 532 may be generated internal to the electronic device 500 but may also be received at the electronic device. As previously mentioned, the data signal may be, for instance, a video signal.

The electronic device 500 also includes a diagnostic component 520 configured to use the quality parameter contour generated by the contour generation circuitry 510 to perform diagnostics on the data signal accessible at the electronic device. Accordingly, the electronic device 500 is capable of performing self-diagnostics by evaluating the quality of signal generated by, or received at, the electronic device.

Accordingly, the principles described herein provide a testing device that may be compact and used to generate a contour of quality parameters of a particular data signal. The contour may be evaluated to ensure quality of signal. The testing device may be compact enough to fit within the very device under test that is being tested, allowing the device under test to be self-testing. Accordingly, the reliability and performance of signal generation device may be more easily verified.

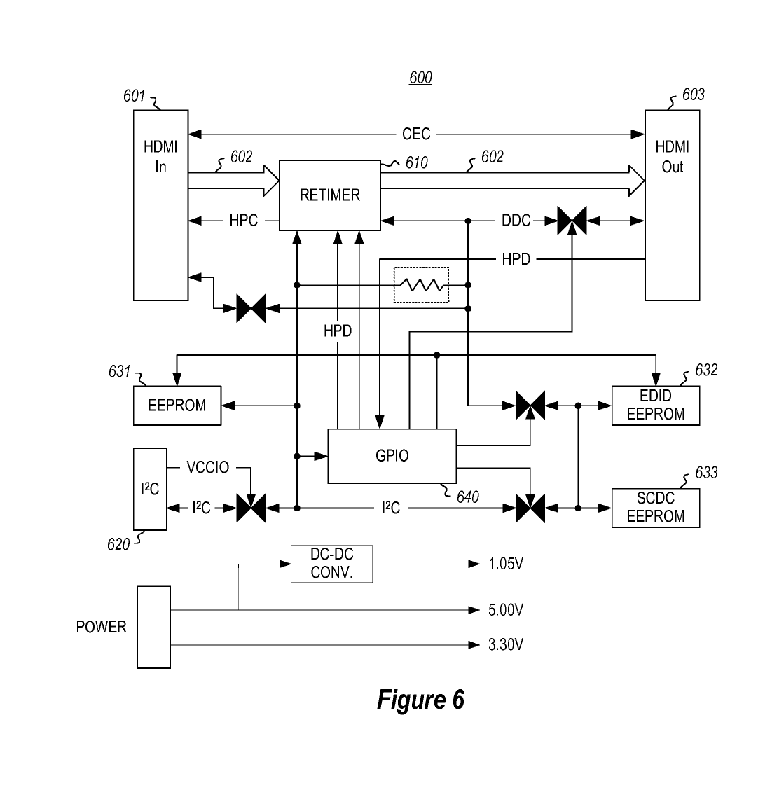

FIG. 6 illustrates a module-level circuit diagram of an example testing environment 600 of the testing environment of FIG. 1. The device under test (e.g., the device under test 101 of FIG. 1) provides a data stream (in the case of FIG. 6, a video stream) to the HDMI In port 601. The retimer 610 represents a repurposed device that acts also as a testing device that operates as described above for the testing device 110 of FIG. 1. In this case, the retimer 610 is acting in pass-through mode and thus the video stream 602 provided at the HDMI In port 601 passes through the retimer 610 and to the HDMI Out port 603.

The quality parameter contour is built from reading from the timer 610 into I2C registers and writing I2C registers to the retimer 610. For instance, the testing environment includes an I2C module 620 to allow such communication to occur. The contour may then be stored in a computer (not shown). The EEPROMs 631, 632 and 633 may store any useful information, such as serial number information.

The HPD signal is a signal that goes into the device under test. It is either driven by the retimer 610, or it essentially mirrors the HPD on the HDMI-Out side (whereby, when you plug in a monitor, the monitor generates HPD which is mirrored through testing device 610 to the device under test The GPIO module 640 is known as a I²C Port Expander. GPIO does stand for General Purpose Input/Ouput. The port expander allows a PC with an i2c interface to control or get status of various signals on the board. It controls LEDS, resets chips, allows Mirroring of the HPD, controls various FET switches to change from passthrough mode to HDMI Sink mode.

As used in this specification and claims, the terms “for example”, “for instance”, “like”, and “such as,” and the verbs “comprising,” “having,” “including,” and their other verb forms, when used in conjunction with a listing of one or more components or other items, are each to be construed as open-ended, meaning that that the listing is not to be considered as excluding other, additional components or items. Other terms are to be construed using their broadest reasonable meaning unless they are used in a context that requires a different interpretation.

It is to be understood that the foregoing description is not a definition of the invention itself, but is a description of one or more example embodiments of the invention. The present invention may be embodied in other specific forms without departing from its spirit or essential characteristics. The invention is not limited to the particular embodiment(s) disclosed herein, but rather is defined solely by the claims below. The scope of the invention is, therefore, indicated by the appended claims rather than by the foregoing description. All changes which come within the meaning and range of equivalency of the claims are to be embraced within the scope.

The described embodiments are to be considered in all respects only as illustrative and not restrictive. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

What is claimed is:

1. A testing device comprising:
an integrated circuit having quality parameter contour generation circuitry configured to generate a quality parameter contour of a data signal received at the contour generation circuitry; and
device under test communication circuitry configured to generate an instruction structured to be recognizable by a device under test as triggering the device under test to emit the data signal towards the contour generation circuitry.

2. The testing device in accordance with claim 1, the integrated circuit being a repurposed integrated circuit configured to perform a primary function that is different than generating a quality parameter contour of a data signal.

3. The testing device in accordance with claim 1, further comprising:
a pass through circuit that is configured to pass through a received signal when the contour generation circuitry is operating to not receive and sink the data signal.

4. The testing device in accordance with claim 1, the testing circuit incorporated within a consumer device to implement diagnostic testing of the received data signal.

5. The testing device in accordance with claim 1, the integrated circuit further configured to perform retiming.

6. The testing device in accordance with claim 1, the integrated circuit comprising a field-programmable gate array.

7. The testing device in accordance with claim 1, the data signal being a video signal, the device under test being a video source.

8. A method for testing a device under test, the method comprising:
an act of device under test communication circuitry communicating with the device under test so to as cause the device under test to send a data signal towards the integrated circuit; and
an act of the integrated circuit receiving the data signal and generating a quality parameter contour of the received data signal.

9. The method in accordance with claim 8, further comprising:
an act of stopping generating the quality parameter contour of the received data signal.

10. The method in accordance with claim 9, further comprising the following in response to the act of stopping:
an act of passing through the received signal.

11. The method in accordance with claim 8, further comprising:
an act of passing through the received signal prior to the act of integrated circuit generating the quality parameter contour of the received data signal.

12. The method in accordance with claim 8, further comprising:
an act of generating the data signal.

13. The method in accordance with claim 8, the data signal being a video signal.

14. The method in accordance with claim 8, the method performed by a testing circuit incorporated into a consumer device to implement diagnostic testing of the received data signal.

15. The method in accordance with claim 8, the method performed by a field-programmable gate array.

16. An electronic device capable of self-testing, the electronic device comprising:
quality parameter contour generation circuitry configured to generate a quality parameter contour of a data signal accessible at the electronic device; and
a diagnostic component configured to use the quality parameter contour generated by the contour generation circuitry to perform diagnostics on the data signal accessible at the electronic device.

17. The electronic device in accordance with claim 16, the accessible data signal being data received at the electronic device.

18. The electronic device in accordance with claim 16, the accessible data signal being data generated at the electronic device.

19. The electronic device in accordance with claim 16, the electronic device being a consumer electronic device.

20. The electronic device in accordance with claim 16, the accessible data signal being a video signal.
